(19) United States
(12) Patent Application Publication
(10) Pub. No.: US 2025/0278028 A1
(43) Pub. Date: Sep. 4, 2025

(54) SHORTWAVE INFRARED INSPECTION OF PATTERNED SUBSTRATES USING FOCUS AVERAGING

(71) Applicant: APPLIED MATERIALS, INC., Santa Clara, CA (US)

(72) Inventors: Ulrich Mueller, Berkeley, CA (US); Jang Fung Chen, Cupertino, CA (US); Thomas L. Laidig, Richmond, CA (US); Chia-Hung Kao, Keelung City (TW)

(21) Appl. No.: 19/052,083

(22) Filed: Feb. 12, 2025

Related U.S. Application Data
(60) Provisional application No. 63/559,268, filed on Feb. 29, 2024.

(51) Int. Cl. G03F 7/00

(52) U.S. Cl. CPC G03F 7/7065; G03F 7/706831; G03F 7/706837

(57) ABSTRACT

A system includes a memory and at least one processing device, operatively coupled with the memory, to obtain metrology data with respect to a substrate, cause a lithography process to be performed using the metrology data to obtain a patterned substrate to be processed, and after performing the lithography process, cause a shortwave infrared (SWIR) inspection system to inspect the patterned substrate by focus averaging a plurality of images of the patterned substrate. Each image of the plurality of images corresponds to a respective SWIR wavelength of a plurality of SWIR wavelengths.

### RELATED APPLICATIONS

This application claims the benefit of U.S. Provisional Application No. 63/559,268, filed Feb. 29, 2024, the entire contents of which are hereby incorporated by reference herein.

### TECHNICAL FIELD

Embodiments of the present disclosure relate to metrology, and more particularly to shortwave infrared (SWIR) inspection of patterned substrates using focus averaging.

### BACKGROUND

Photolithography is widely used in the manufacturing of semiconductor devices and display devices, such as liquid crystal displays (LCDs). Large area substrates are often utilized in the manufacture of LCDs. LCDs, or flat panels, are commonly used for active matrix displays, such as computers, touch panel devices, personal digital assistants (PDAs), cell phones, television monitors, and the like. Generally, flat panels include a layer of liquid crystal material forming pixels sandwiched between two plates. When power from a power supply is applied across the liquid crystal material, an amount of light passing through the liquid crystal material is controlled at pixel locations enabling images to be generated. Other manufacturing techniques are used to produce organic light emitting diode (“OLED”) displays for use in computers, monitors and other systems providing visual output.

Microlithography techniques have been employed to create electrical features incorporated as part of the liquid crystal material layer forming the pixels. According to these techniques, a light-sensitive photoresist is applied to at least one surface of the substrate. Then, a pattern generator exposes selected areas of the light-sensitive photoresist as part of a pattern with light to cause chemical changes to the photoresist in the selective areas to prepare these selective areas for subsequent material removal and/or material addition processes to create the electrical features.

### SUMMARY

In some embodiments, a system is provided. The system includes a memory and at least one processing device, operatively coupled with the memory, to obtain metrology data with respect to a substrate, cause a lithography process to be performed using the metrology data to obtain a patterned substrate to be processed, and cause a shortwave infrared (SWIR) inspection system to inspect the patterned substrate by focus averaging a plurality of images of the patterned substrate. Each image of the plurality of images corresponds to a respective SWIR wavelength of a plurality of SWIR wavelengths.

In some embodiments, a method is provided. The method includes obtaining, by at least one processing device, metrology data with respect to a substrate, causing, by the at least one processing device, a lithography process to be performed using the metrology data to obtain a patterned substrate to be processed, and causing, by the at least one processing device, a shortwave infrared (SWIR) inspection system to inspect the patterned substrate by focus averaging a plurality of images of the patterned substrate. Each image of the plurality of images corresponds to a respective SWIR wavelength of a plurality of SWIR wavelengths.

In some embodiments, a system is provided. The system includes a lithography system to perform a lithography process using metrology data to obtain a patterned substrate to be processed, and a shortwave infrared (SWIR) inspection system operatively coupled with the lithography system. The SWIR inspection system includes at least one SWIR wave source to generate multiple SWIR waves each having a respective SWIR wavelength of a plurality of SWIR wavelengths, and a SWIR imaging system including an optical system and at least one image capture device operatively coupled with at least one image sensor. The system further includes a memory and at least one processing device, operatively coupled with the memory, to obtain the metrology data, cause the lithography process to be performed using the metrology data to obtain the patterned substrate, cause the SWIR inspection system to inspect the patterned substrate by focus averaging a plurality of images of the patterned substrate. Each image of the patterned substrate corresponding to a respective SWIR wavelength of the plurality of SWIR wavelengths.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIGS. 1A-1B are diagrams of example photolithography systems, in accordance with some embodiments.

FIG. 2A is a block diagram of a system that can implement shortwave infrared (SWIR) inspection of patterned substrates using focus averaging, in accordance with some embodiments.

FIG. 2B is a diagram of an example shortwave infrared (SWIR) inspection system, in accordance with some embodiments.

FIG. 3 is a diagram of an example shortwave infrared (SWIR) imaging system that can be used to implement a SWIR inspection system, in accordance with some embodiments.

FIG. 4 is a timing diagram illustrating example operation of a shortwave infrared (SWIR) inspection system, in accordance with some embodiments.

FIGS. 5A-5B are diagrams of example layout plots, in accordance with some embodiments.

FIGS. 6, 7A and 7B are flow diagrams of example methods for implementing shortwave infrared (SWIR) inspection of patterned substrates using focus averaging, in accordance with some embodiments.

FIG. 8 illustrates a diagrammatic representation of an example computer system, in accordance with some embodiments.

### DETAILED DESCRIPTION

Embodiments of the present disclosure relate to shortwave infrared (SWIR) inspection of patterned substrates using focus averaging. For example, SWIR inspection can include broadband SWIR inspection. One example of a patterned substrate is a patterned silicon (Si) substrate. In some implementations, a patterned substrate includes one or more chiplets. A chiplet refers to an integrated circuit that implements a particular function. A chiplet can be combined with other chiplets on an interposer to form a single package. For example, the package can include a system-on-chip (SoC).

Patterned substrates (e.g., wafers) can be inspected using a SWIR inspection section that causes an optical wave (i.e., light) having a wavelength in the SWIR range (“SWIR wavelength”) of the electromagnetic spectrum to be generated. Generally, the infrared (IR) range can be defined by a lower bound wavelength of about 760 nanometers (nm) and an upper bound wavelength of about 100,000 nm. For example, each SWIR wave can have a wavelength that ranges from about 1050 nm to about 1800 nm.

A SWIR wave can be generated by a SWIR wave source. For example, a SWIR wave source can be a laser. As another example, a SWIR wave source can be a light emitting diode (LED). As yet another example, a SWIR wave source can be a lamp (e.g., broadband lamp) with filters. SWIR wave sources (e.g., lasers, LEDs and/or lamps) can cover a range above the bandgap of a material of a substrate. For example, the bandgap of Si is about 1054 nm.

A SWIR inspection system can include a SWIR imaging system. The SWIR imaging system can include an optical system that can be used to direct a SWIR wave received from a SWIR wave source toward a patterned substrate for imaging of the patterned substrate. For example, the SWIR wave can travel from the SWIR wave source toward a set of lens elements of the optical system via an optical fiber. The optical system can further include an objective (e.g., microscope objective) that can direct a SWIR wave toward the patterned substrate, and focus a SWIR wave reflected off the patterned substrate to generate a focused SWIR wave.

The SWIR imaging system can further include at least one image capture device (e.g., camera) to receive the focused SWIR wave. For example, an image capture device can have a shutter which can be opened to closed to allow the focused SWIR wave to enter a lens of the image capture device. An image capture device can further include, or be operatively coupled to, an image sensor to detect the focused SWIR wave. An image sensor can include, or can be operatively coupled with, at least one processing device to process the detected SWIR wave to generate image data.

The SWIR imaging system can generate multiple images of a patterned substrate by scanning across the patterned substrate from an initial location to a final location. The patterned substrate can include multiple features that are inspected from the images. Examples of features of a patterned substrate include alignment marks, vias, edges (e.g., chip edges), etc. However, as a patterned substrate undergoes processing, building up layers of circuits and device features, it can be become more difficult for an IR inspection system to focus SWIR waves onto the surface of the substrate. Each wavelength (or frequency) of a SWIR wave can have a corresponding optimal focus to generate an optimal image of the patterned substrate. A focus can generally be defined by distance below the lens system (e.g., objective), and an optimal focus for a particular wavelength can be an optimal distance between the patterned substrate and the lens system from which the patterned substrate can be imaged using the particular wavelength. Since each wavelength can have an optical focus, it may not be possible to precisely detect the locations of multiple features of the patterned substrate by scanning the patterned substrate using a typical IR inspection system. This can have a particular impact on, e.g., higher magnification applications of patterned substrate inspection in which depth of focus becomes small and/or precise focus control may be needed.

In some implementations, the SWIR imaging system includes multiple image capture devices, where the optical system includes elements that are designed to route each focused SWIR wave reflected off a patterned substrate to a respective image capture device. However, it may not be practical to implement such a multi-image capture device system. For example, image capture devices can be costly. As another example, adding image capture devices can require adding elements in the optical system to direct SWIR waves to their respective image capture devices, which can further increase cost and can contribute to SWIR wave power loss.

Embodiments described herein can improve the ability of a SWIR inspection system to inspect a patterned substrate and detect the locations of features of the patterned substrate by generating a focus-averaged image using a single image sensor. The patterned substrate can be disposed on a stage. The stage can move the patterned substrate in multiple directions. Each SWIR wave can be generated by a respective SWIR wave source (e.g., laser, LED, or lamp).

In some embodiments, the multiple SWIR waves generated by the at least one SWIR wave source travel through a common optical fiber to the SWIR imaging system. For example, the multiple SWIR waves generated by the at least one SWIR wave source can be combined to travel through the common optical fiber via multiplexing. In some embodiments, multiplexing is wavelength-division multiplexing (WDM). In some embodiments, at least one SWIR wave generated by the at least one SWIR wave source travels through one optical fiber, and at least one other SWIR wave generated by the at least one SWIR wave source travels through a different optical fiber. In some embodiments, each SWIR wave generated by the at least one SWIR wave source travels through a respective optical fiber.

The SWIR inspection system can include a SWIR imaging system including an optical system that can direct multiple SWIR waves, each having a respective SWIR wavelength, to the patterned substrate. The SWIR waves reflected off the patterned substrate can be received by at least one image capture device (e.g., camera). The SWIR imaging system can further include at least one image sensor, which can be included within the at least one image capture device or can be operatively coupled to the at least one image capture device, that can detect the multiple focused SWIR waves reflected off of the patterned substrate, and generate a focused-averaged image of the patterned substrate based on the multiple focused SWIR waves. Accordingly, the combination of the multiple focused signals creates a focus-averaging effect that accounts for the variance in optimal foci across various wavelengths.

A controller, including at least one processing device, can control operation of components of the SWIR imaging system to improve scanning and image quality. The controller can control the multiple SWIR wave sources, the at least one image capture device, the stage, etc. For example, the controller can control the timing of the opening/closing of the shutter and when optical waves are to be provided by the at least one optical wave source. More specifically, the controller can cause the multiple SWIR wave sources (e.g., lasers, LEDs and/or bulbs) to generate the SWIR waves (e.g., flash) independent of the exposure time of the shutter of the at least one image capture device. The SWIR wave sources can be synchronized to the motion of the patterned substrate (e.g., motion of the stage) via position sensors, which send position data to the controller. The patterned substrate inspection locations can be predefined via an inspection layout file. From the position data, the controller can control the opening and/or closing of the camera shutter using a position-based trigger signal. The controller can cause the SWIR wave sources to generate SWIR waves (e.g., enable the SWIR wave sources) based on the position of the patterned substrate (e.g., the position of the stage), which can be determined from the position sensors. Additionally, the controller can cause the SWIR wave sources to stop generating SWIR waves (e.g., disable the SWIR wave sources) after a defined time. For example, the defined time can be determined as a function of the speed of the stage. The controller can control exposure time by controlling SWIR wave source operation, instead of shutter operation. This can enable the SWIR inspection system to scan across the surface of the patterned substrate more quickly with reduced image smearing, which can improve scanning throughput and image quality.

In some embodiments, the SWIR inspection system implements a metrology inspection method (e.g., inline metrology) for digital lithography. In digital lithography tools, images can be used to find a position of alignment marks so that processing may occur across at a known location. In order to obtain the images, image capture devices can be calibrated and specially chosen for pixel size, orientation (rotation) and uniformity.

One of the major challenges of microlithography systems is placement of wiring between components. Often, arrangements of concern involve a fixed outer periphery to a component placed on an inside of a defined area. Wiring must be placed from the fixed periphery (which may be a connection point to another component) to individual connection points, such as die, of the component on the inside of the defined area.

Embodiments described herein can provide for numerous other technical advantages. For example, embodiments described herein can improve the focus margin and detection accuracy as a patterned substrate is being scanned by the SWIR inspection system, with only a single image capture device and image sensor. Accordingly, embodiments described herein can improve the ability of a SWIR inspection system to image and inspect features of a patterned substrate in a more cost-effective manner.

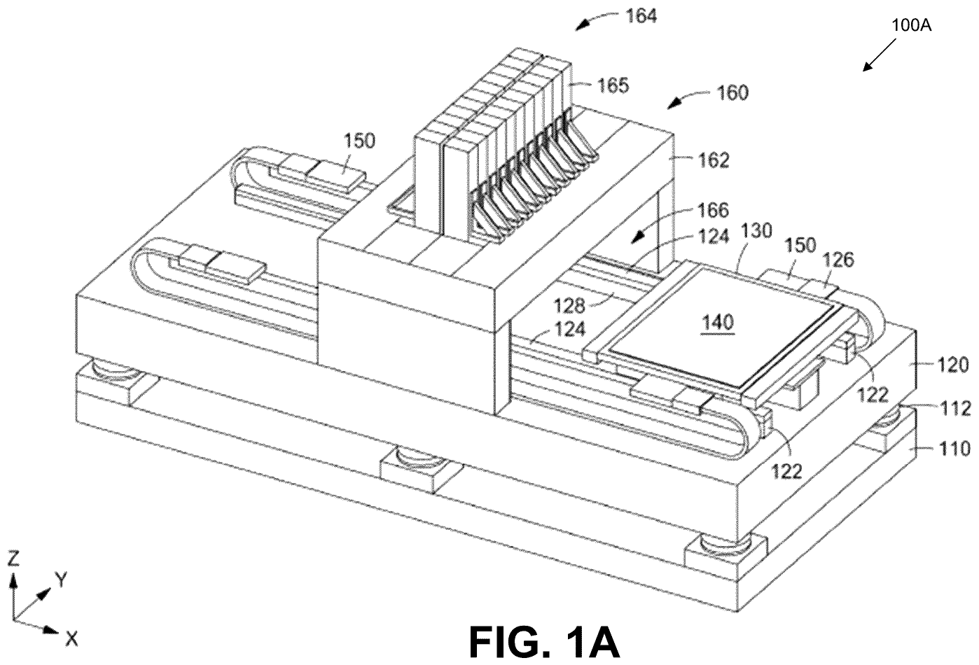

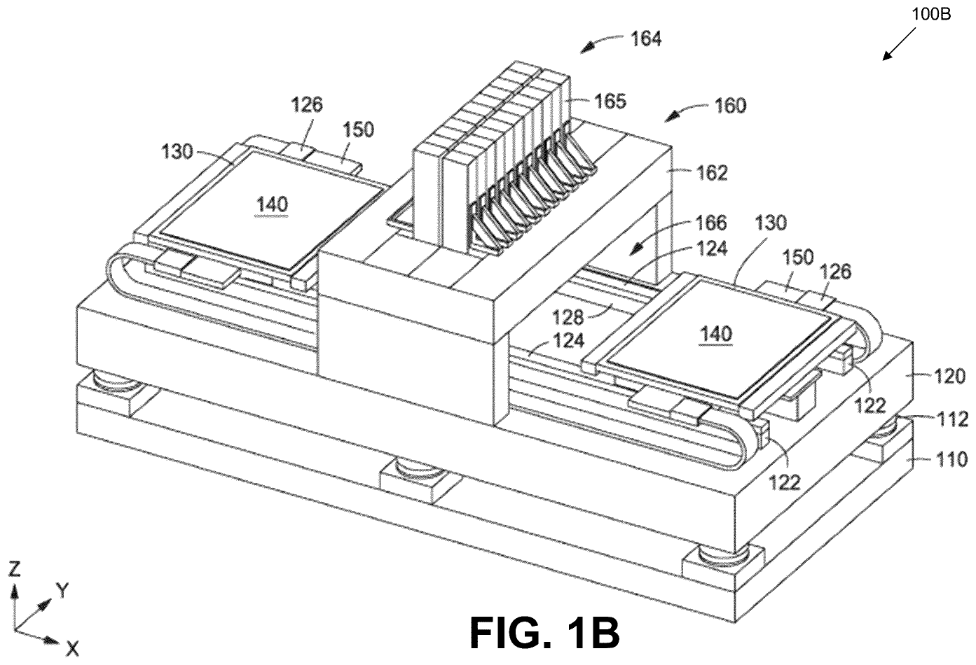

FIG. 1A is a perspective view of a photolithography system (“system”) 100A, in accordance with some embodiments. The system 100A includes a base frame 110, a slab 120, a stage 130, and a processing apparatus 160. The base frame 110 rests on the floor of a fabrication facility and supports the slab 120. Passive air isolators 112 are positioned between the base frame 110 and the slab 120. In one embodiment, the slab 120 is a monolithic piece of granite, and the stage 130 is disposed on the slab 120. A substrate 140 is supported by the stage 130. Multiple holes (not shown) can be formed in the stage 130 for allowing multiple respective lift pins (not shown) to extend therethrough. In some embodiments, the lift pins rise to an extended position to receive the substrate 140, such as from one or more transfer robots (not shown). The one or more transfer robots are used to load and unload a substrate 140 from the stage 130.

The substrate 140 includes any suitable material, for example, quartz used as part of a flat panel display. In other embodiments, the substrate 140 is made of other materials. In some embodiments, the substrate 140 has a photoresist layer formed thereon. A photoresist is sensitive to radiation. A positive photoresist includes portions of the photoresist, which when exposed to radiation, will be respectively soluble to photoresist developer applied to the photoresist after the pattern is written into the photoresist. A negative photoresist includes portions of the photoresist, which when exposed to radiation, will be respectively insoluble to photoresist developer applied to the photoresist after the pattern is written into the photoresist. The chemical composition of the photoresist determines whether the photoresist will be a positive photoresist or negative photoresist. Examples of photoresists include, but are not limited to, at least one of diazonaphthoquinone, a phenol formaldehyde resin, poly(methyl methacrylate), poly(methyl glutarimide), and SU-8. In this manner, the pattern is created on a surface of the substrate 140 to form the electronic circuitry.

The system 100A includes a pair of supports 122 and a pair of tracks 124. The pair of supports 122 are disposed on the slab 120, and the slab 120 and the pair of supports 122 are a single piece of material. The pair of tracks 124 is supported by the pair of the supports 122, and the stage 130 moves along the tracks 124 in the X-direction. In one embodiment, the pair of tracks 124 is a pair of parallel magnetic channels. As shown, each track 124 of the pair of tracks 124 is linear. In other embodiments, one or more track 124 is non-linear. An encoder 126 is coupled to the stage 130 in order to provide location information to a controller (not shown).

The processing apparatus 160 includes a support 162 and a processing unit 164. The support 162 is disposed on the slab 120 and includes an opening 166 for the stage 130 to pass under the processing unit 164. The processing unit 164 is supported by the support 162. In one embodiment, the processing unit 164 is a pattern generator configured to expose a photoresist in a photolithography process. In some embodiments, the pattern generator is configured to perform a maskless lithography process. The processing unit 164 can include a plurality of image projection apparatus. In one embodiment, the processing unit 164 contains as many as 84 image projection apparatus. Each image projection apparatus is disposed in a case 165. The processing apparatus 160 is useful to perform maskless direct patterning.

During operation, the stage 130 moves in the X-direction from a loading position, as shown in FIG. 1A, to a processing position. The processing position is one or more positions of the stage 130 as the stage 130 passes under the processing unit 164. During operation, the stage 130 is be lifted by a plurality of air bearings (not shown) and moves along the pair of tracks 124 from the loading position to the processing position. A plurality of vertical guide air bearings (not shown) is coupled to the stage 130 and positioned adjacent an inner wall 128 of each support 122 in order to stabilize the movement of the stage 130. The stage 130 also moves in the Y-direction by moving along a track 150 for processing and/or indexing the substrate 140. The stage 130 is capable of independent operation and can scan a substrate 140 in one direction and step in the other direction.

A metrology system can measure the X and Y lateral position coordinates of the stage 130 in real time so that each of the plurality of image projection apparatus can accurately locate the patterns being written in a photoresist covered substrate. The metrology system can also provide a real-time measurement of the angular position of each of the stage 130 about the vertical or Z-axis. The angular position measurement can be used to hold the angular position constant during scanning by means of a servo mechanism or it can be used to apply corrections to the positions of the patterns being written on the substrate 140 by the image projection apparatus. These techniques may be used in combination.

FIG. 1B is a perspective view of a photolithography system (“system”) 100B, in accordance with some embodiments. The system 100B is similar to the system 100A; however, the system 100B includes two stages 130. Each of the two stages 130 is capable of independent operation and can scan a substrate 140 in one direction and step in the other direction. In some embodiments, when one of the two stages 130 is scanning a substrate 140, another of the two stages 130 is unloading an exposed substrate and loading the next substrate to be exposed.

While FIGS. 1A-1B depict two embodiments of a photolithography system (e.g., system 100A and 100B), other systems and configurations are also contemplated herein. For example, photolithography systems including any suitable number of stages are also contemplated.

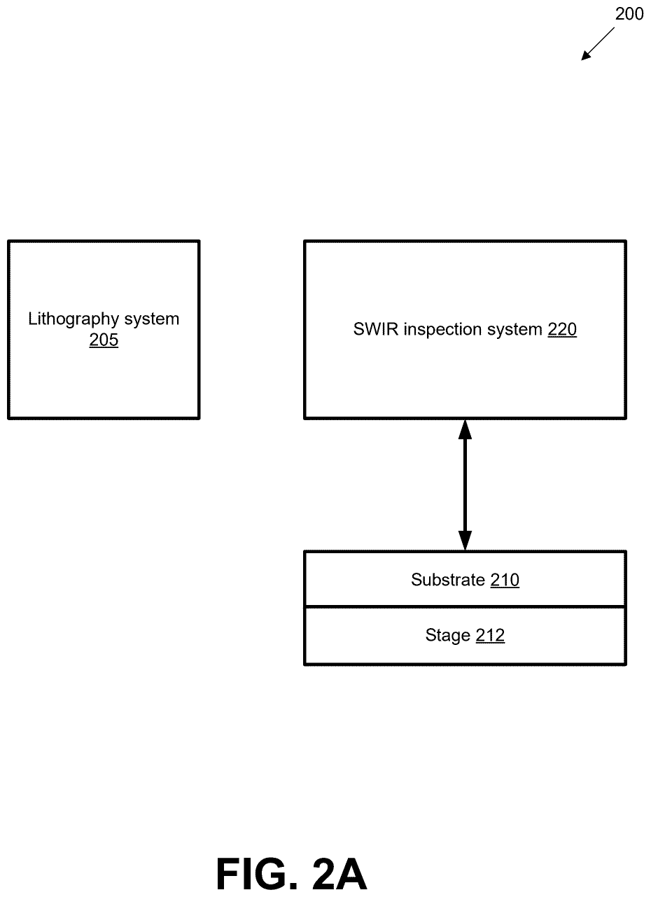

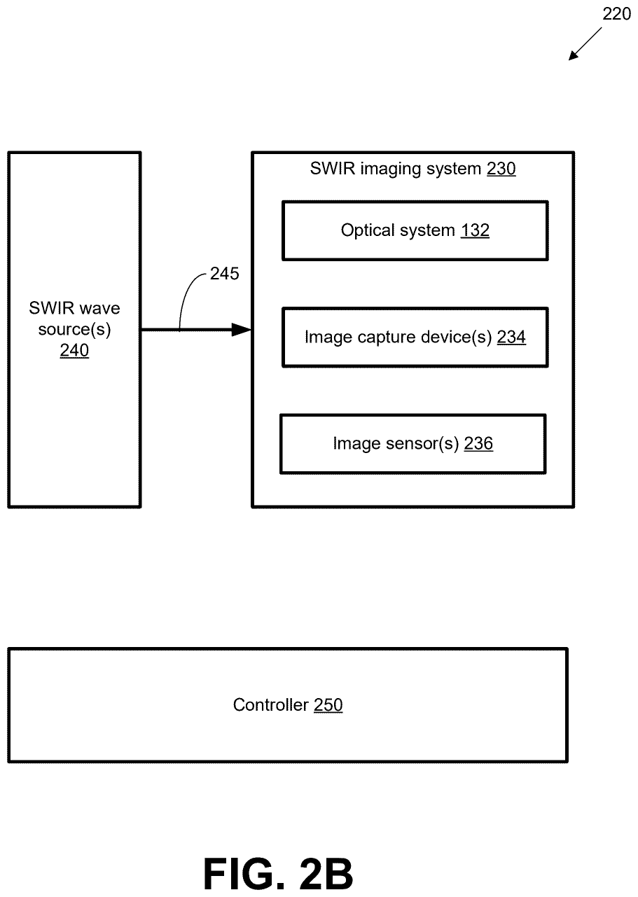

FIG. 2A is a block diagram of a system 200 that can implement SWIR inspection of patterned substrates using focus averaging, in accordance with some embodiments. As shown, system 200 can include lithography system 205 (e.g., lithography system 100A or 100B of FIGS. 1A-1B), substrate 210, and SWIR inspection system 220. In some embodiments, substrate 210 is disposed on stage 212. Examples of SWIR inspection system 220 will be described below with reference to FIGS. 1B-2.

In some embodiments, SWIR inspection system 220 implements a metrology inspection method (e.g., inline metrology) for lithography. For example, lithography system 205 can obtain (e.g., generate) a die metrology file including with die location and orientation data using a pre-lithography die metrology method. Then, lithography system 205 can perform a lithography process using the die metrology file. The lithography process can be performed to generate a substrate design file. For example, the substrate design file can include a digital lithography exposure file that is generated by integrating dynamic data connections (DDC). In some embodiments, lithography system 205 is a digital lithography system that is used to perform digital lithography.

SWIR inspection system 220 can then be used to implement a post-lithography inspection method (e.g., inline inspection process) to generate post-lithography metrology data that can be used to verify the layout of a patterned substrate. For example, the post-lithography metrology data can include die image data that can be used to detect the location and/or orientation of dies, detect edge fractures, etc. As another example, the post-lithography metrology data can include via image data that can be used to detect via defects. The post-lithography inspection method can include at least one of die-to-die inspection comparison, a die to database (e.g., DDC die to database) method that executes a model to generate synthesized expected images, etc. Based on the post-lithography inspection method, it is determined whether the patterned substrate can be etched. If so, then the patterned substrate can be etched. If not, then then lithography data can be updated (e.g., reworked) in order to generate new post-lithography metrology data.

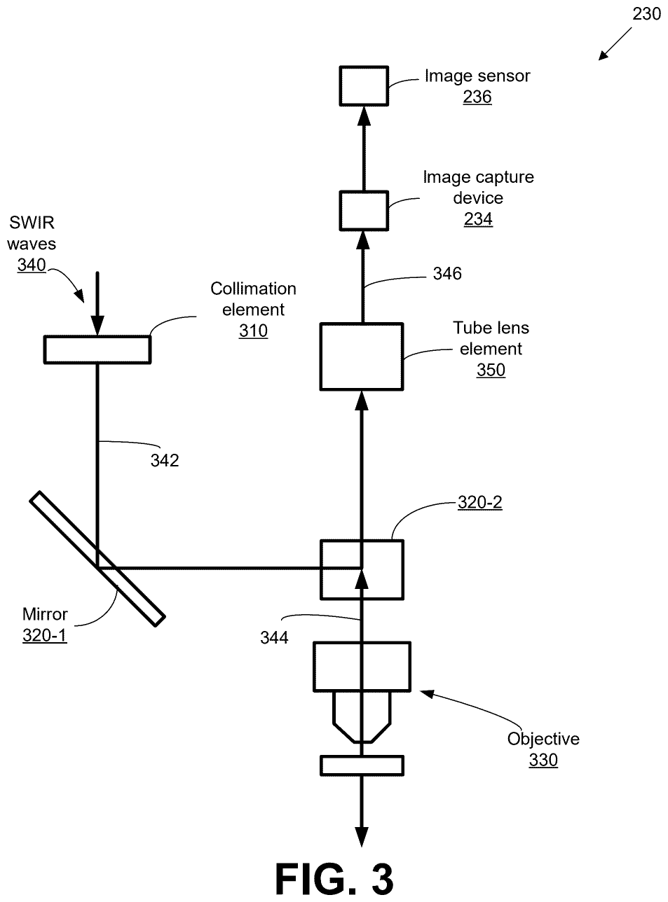

FIG. 2B is a block diagram of an example SWIR inspection system (“system”) 220, in accordance with some embodiments. System 220 can include substrate 210, SWIR imaging system 230, at least one SWIR wave source 240, and controller 250. SWIR imaging system 230 can include optical system 232 including a set of optical components used to direct SWIR waves to and from substrate 210 (e.g., objective, set of lenses, collimator). SWIR imaging system 230 can further include at least one image capture device 234, and at least one image sensor 236. In some embodiments, at least one image capture device 234 includes a camera. An example of SWIR imaging system 230 will be described in further detail below with reference to FIG. 3. In some embodiments, at least one SWIR wave source 240 includes at least one laser. In some embodiments, at least one SWIR wave source includes at least one LED. In some embodiments, at least one SWIR wave source includes a lamp (e.g., broadband lamp) with filters.

As shown in FIG. 2B, at least one SWIR wave source 240 is coupled to SWIR imaging system 230 via at least one optical fiber 245. At least one SWIR wave source 240 can provide (e.g., generate) multiple SWIR waves having a SWIR wavelength (“SWIR waves”) to SWIR imaging system 230 via at least one optical fiber 245. In some embodiments, multiple SWIR wave sources are coupled into a single optical fiber. When the multiple SWIR waves are directed toward the substrate 210 via optical system 232, the multiple SWIR waves reflect off of substrate 210 back to optical system 232 to be directed toward at least one image capture device 234. At least one image sensor 236 can then detect the multiple SWIR waves reflected off of the substrate and generate a focus-averaged image based on the multiple SWIR wavelengths.

Each lens of lens system 232 may be an optical lens formed of any suitable material including, but not limited to, glass, silica, a crystalline material, a nanocrystalline material, and so on. At least one image sensor 236 can include at least one of a linear image sensor, a complementary metal oxide semiconductor (CMOS) or active pixel image sensor, a charge-coupled device (CCD) image sensor, a solid-state device that converts an optical image into an analog signal in a line-by-line fashion, etc.

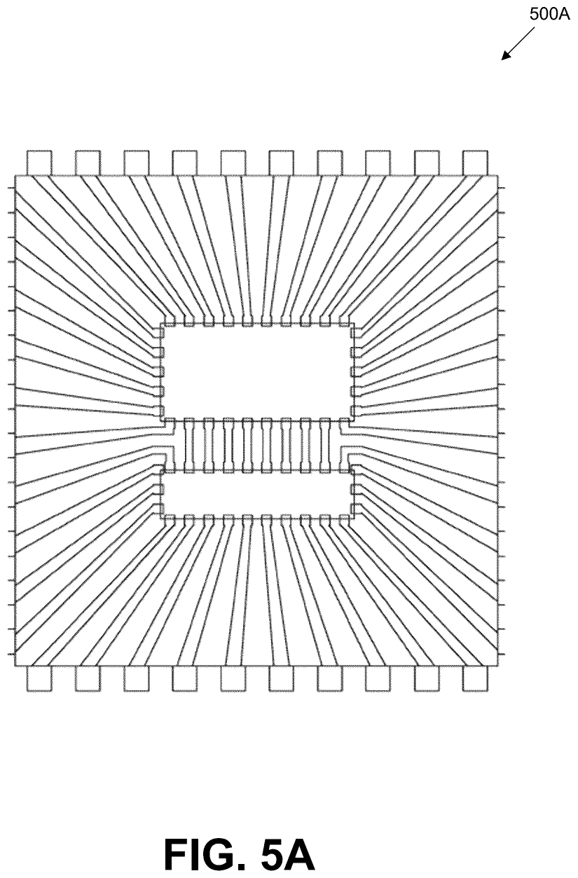

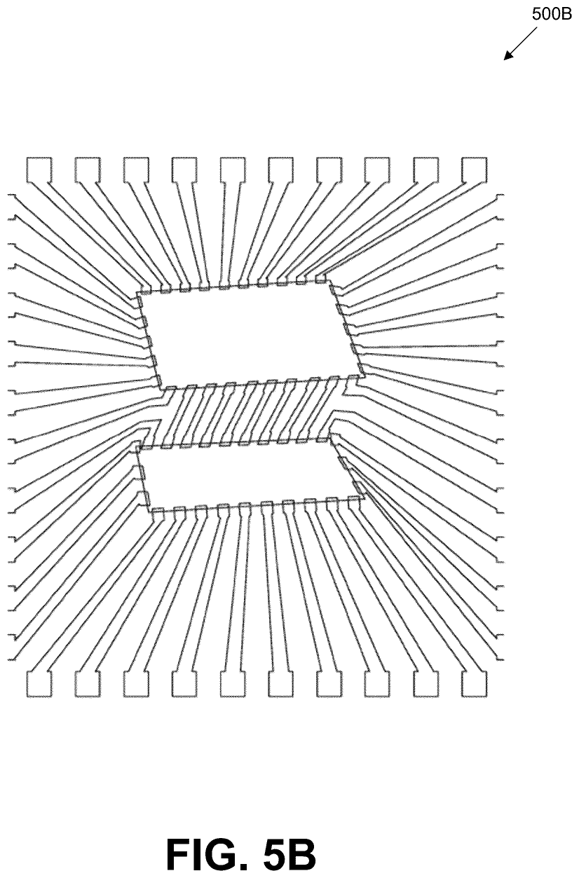

Controller 250 can control the timing of operation of image capture device(s) 234 and SWIR wave source(s) 240 to reduce image smearing. For example, the shutter(s) of image capture device(s) 234 can initially be closed and SWIR wave source(s) 240 can initially be inactive. Controller 250 can cause the shutter(s) of image capture device(s) 234 to open at a particular time or location of substrate 210 relative to SWIR imaging system 230. Controller 250 can determine a second time or location of substrate relative to SWIR imaging system 230 in which to activate SWIR wave source(s) 240, and can activate SWIR wave source(s) 240 at the second time or location to generate the SWIR waves having respective SWIR wavelengths. Controller 250 can then deactivate SWIR wave source(s) after a sufficient amount of time has passed, thus generating respective SWIR wave pulses. Controller 250 can then cause the shutter(s) of the image capture device(s) 234 to close after the image capture device(s) 234 receive the SWIR wave pulses. Further details regarding how controller 250 can control the timing of operation of image capture device(s) 234 and SWIR wave source(s) 240 will be described below with reference to FIG. 5.

During a subsequent scan of the substrate 210, the position (e.g., height) of the substrate 210 may change. For example, the vertical position of the substrate may change to reduce the distance between substrate 210 and SWIR imaging system 230. An example of SWIR imaging system 230 will now be described below with reference to FIG. 2.

FIG. 3 is a diagram 300 of an example SWIR imaging system 230, in accordance with some embodiments. As shown, the optical system (e.g., optical system 232 of FIG. 1B) can include a collimation element 310 (e.g., focusing lens element), mirror 320-1, optical cube 320-2, and objective 230. For example, as shown, mirror 320-1 is an angled mirror. In some embodiments, mirror 320-1 is angled between about 40 degrees to about 50 degrees relative to a horizontal plane. Optical cube 320-2 may be a prism, for example, designed to reflect the collimated SWIR waves 342 from mirror 320-1. In some embodiments, optical cube 320-2 may be replaced by some other optical element, such as another mirror.

As further shown, SWIR waves 340 are directed toward collimation element 310. SWIR waves 340 can be generated by at least one SWIR wave source (e.g., SWIR wave source(s) 240 of FIG. 2B) and sent to collimation element 310 via at least one optical fiber (e.g., at least one optical fiber 245 of FIG. 2B). Collimation element 310 can generate collimated SWIR waves 342 that are directed toward mirror 320-1, which are then reflected toward optical cube 320-2. Optical cube 320-2 reflects the collimated SWIR waves 342 toward a patterned substrate (not shown) located beneath objective 330 (e.g., substrate 210 of FIG. 2B). Reflected SWIR waves reflected off the patterned substrate can then be received by objective 330 to generate objective SWIR waves 344. Objective 330 can include any suitable optical elements.

In some embodiments, SWIR imaging system 230 is an infinity-corrected optical system. For example, as shown, SWIR imaging system 230 can includes tube lens element 350 that is designed to receive objective SWIR waves 344, and perform infinity-correction on objective SWIR waves 344 to generate infinity-corrected focused (“focused”) SWIR waves 346. The distance between objective 330 and tube lens element 350 is referred to as the “infinity space” of the infinity-corrected optical system. In some embodiments, SWIR imaging system 230 is a finite-corrected optical system that does not include tube lens element 350, and objective SWIR waves 344 are finite-corrected focused SWIR waves.

Focused waves 346 (or 344 in the case of a finite-corrected optical system) can then be received by image capture device 234 operatively coupled to image sensor 236 to detect focused waves 346 (or 344) and generate a focus-averaged image from focused waves 346 (or 344).

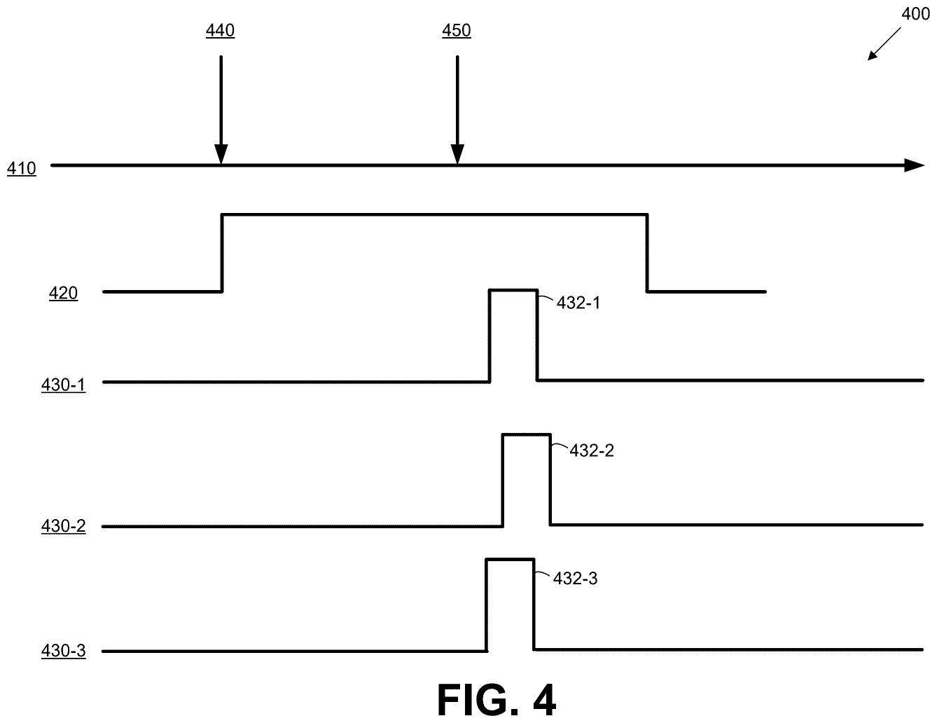

FIG. 4 is a timing diagram 400 illustrating example operation of a SWIR inspection system, in accordance with some embodiments. For example, the SWIR inspection system can be similar to SWIR inspection system 220 described above with reference to FIGS. 2A-3 and can include SWIR imaging system 230 described above with reference to FIGS. 2B-3.

As shown, timing diagram 400 includes line 410 illustrating the location of a substrate that is moving on a stage, line 420 illustrating the state of a shutter of an image capture device as the substrate is moving (e.g., open or closed), and lines 430-1 through 430-3 each illustrating operation of a respective SWIR wave source used to generate a SWIR wave having a respective SWIR wavelength.

At location 440, and as indicated by line 420, a controller of the SWIR inspection system causes the shutter of the image capture device to be opened. Location 440 is some location behind a target location of the substrate from which an image will be captured, indicated by location 450. Upon reaching location 450, the controller causes each SWIR wave source to generate a respective SWIR wave pulse. The SWIR wave sources are not activated to generate the respective SWIR waves until location 450 to prevent image smearing due to the motion of the substrate.

In processing of materials through the lithography system, components with one or more dice are placed on a stage for processing. While an ideal layout of the components may be achieved for processing, various factors may impact such ideal layout. Processing speed of the lithography system may slightly move the components as the lithography system handles the components. These slight movements, for components that are small, can have drastic impact on the final product as wiring from an origination point to ending point can be small. Each component, furthermore, may have several dice, therefore many connections may be impacted by incorrect alignment of the component compared to a “perfect” or ideal layout.

Aspects of the disclosure provide that given an ideal placement of one or more dice within a packaging layout as well as actual placements that may involve some errors, the ideal placement may be modified or distorted to match the actual placements, thereby adaptively generating routing for packaging of dice into a larger assembly.

Referring to FIG. 5A, an ideal layout plot 500A is shown. Such an ideal layout plot would occur if each of the components is placed, as intended, on a substrate for processing. As will be understood, placement of components with extremely high accuracy can be difficult. To this end, even if the component is placed with high accuracy, shifting may occur during processing, as digital lithography systems move large substrates at fast speeds.

Referring to FIG. 5B, an actual layout plot 500B is shown. As can be seen, a component is shifted from the position of the idea layout plot 500A shown in FIG. 5A. An altered wiring connection to the component is therefore required in order for the component to operate correctly. To this end an augmented wiring scheme is produced such that the wiring is proper.

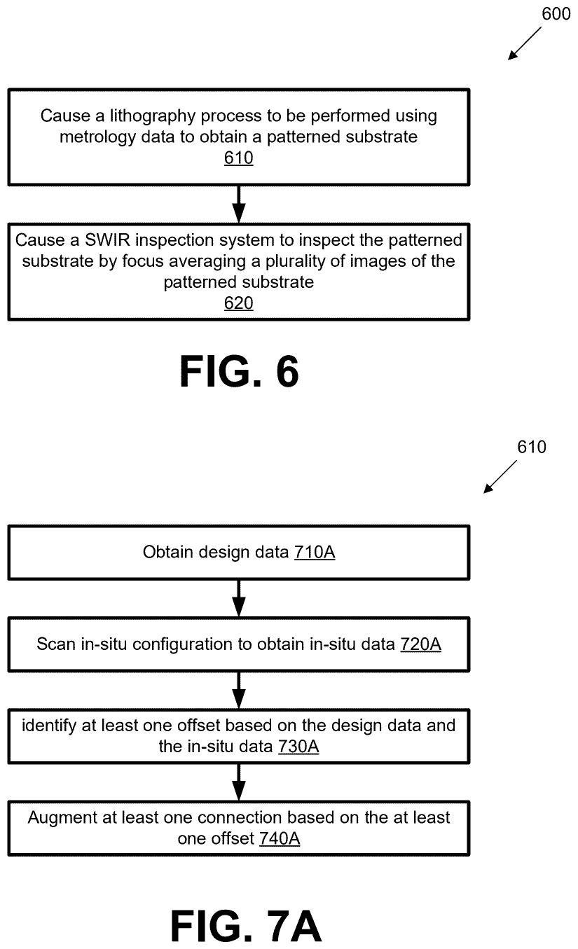

FIG. 6 is a flow diagram of a method 600 for implementing SWIR inspection of patterned substrates using focus averaging, according to some embodiments. Method 600 can be performed by processing logic comprising hardware, software, firmware, or any combination thereof. In at least one embodiment, method 600 is performed by a controller or control system, such as controller 250 described above with reference to FIG. 2B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other diagrams are possible.

At operation 610, processing logic causes a lithography process to be performed using metrology data to obtain a patterned substrate. In some embodiments, the metrology data is maintained within a die metrology file. In some embodiments, obtaining the metrology data includes generating the metrology data (e.g., generating the die metrology file). In some embodiments, the lithography process is a digital lithography process.

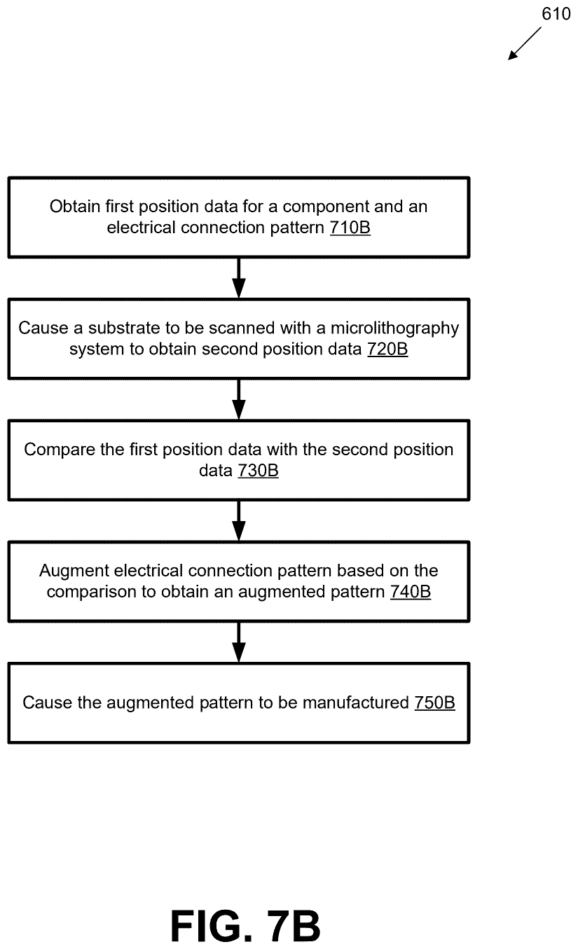

At operation 620, processing logic causes a SWIR inspection system to inspect the patterned substrate using focus averaging based on a plurality of images of the patterned substrate. For example, SWIR inspection system 220 can capture a number of images of a patterned substrate (e.g., a silicon (Si) substrate) using optical waves (e.g., light) having respective wavelengths, and each image may be a respective image clarity and/or focus. For example, a first image may be obtained using visible light. A second image may be obtained using SWIR light having a wavelength of about 1000 nm, which is toward the low end of the SWIR spectrum. A third image may be obtained using SWIR light having a wavelength of about 1100 nm. A fourth image may be obtained using SWIR light having a wavelength of about 1300 nm. A fifth image may be obtained using SWIR light having a wavelength of about 1400 nm. A sixth image may be obtained using SWIR light having a wavelength of about 1500 nm. A seventh image may be obtained using SWIR light having a wavelength of about 1500 nm. An eight image may be obtained using SWIR light having a wavelength of about 1600 nm. SWIR inspection system 220 may use the captured images to generate a focus-averaged image by averaging the multiple images obtained using multiple SWIR wavelengths of light. Selecting multiple SWIR wavelengths to inspect features of the patterned substrate (e.g., alignment marks, vias, chip edges, etc.) can enable more precise detection of the locations of these features. Further details regarding operations 610-620 are described above with reference to FIGS. 2A-6B and will now be described below with reference to FIGS. 7A-7B.

FIG. 7A is a flow diagram of a method 610 for causing a lithography process to be performed using metrology data. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other diagrams are possible.

At operation 710A, processing logic obtains design data. Examples of design data include coordinate data of a component as well as a connection pattern to the component in a designed state. Design data may be obtained from manufacturing drawings, for example. The component may be any type of component that needs wiring attachment, such as, but not limited by, processors. Wiring may be, for example, from the component to a fixed external area, such that when components are eventually separated, the wiring ends at a predetermined location. The component can be positioned within a defined field for processing. The actual (x,y) components may vary slightly from various factors, including the ability of locating such components accurately during initial processing of the platen (indexing table) before loading of the platen into the microlithography machine. Other factors may also cause the component to move, such as handling of the components during microlithography steps.

At operation 720A, processing logic scans an in-situ configuration to obtain in-situ data. For example, to achieve a wiring connection to the component that extends to the fixed outer field, the “in-situ” positioning of the components on the platen are scanned with at least one scanning device to be able to ascertain the exact positioning of each component. The platen, therefore, is moved into a position in the lithography system such that the scanning occurs for processing of coordinate data. As will be understood, scanning of the actual condition may also be accomplished by a separate process, if needed, and the data fed to the microlithography machine for use.

At operation 730A, processing logic identifies at least one offset based on the design data and the in-situ data. For example, the design data can be compared to the in-situ data to determine whether any offsets are present in the actual placement of the components compared to the ideal-designed positioning. An offset may be identified to allow the microlithography machine to understand the exact placement of the components. Computer analysis of the data may be performed to determine the required offset. The computer analysis may not only calculate the offset, but also provide new connection wiring locations between the component and the fixed perimeter, therefore speeding processing.

At operation 740A, processing logic augments at least one connection based on the at least one offset. For example, a connection pattern from the ideal designed condition may then be augmented using the at least one offset. Visual image data may also be used to determine the difference that is needed for the connection pattern.

In some embodiments, hardware architects may determine that slight variations from ideal placement are allowable. The deviation for the wiring connection and the component may be determined to be within acceptable levels. In those instances, no alteration of the wiring connection may be required. When deviations from these acceptable levels are found, a warning may be generated to the processors to allow for notification that alterations/modification of the wiring are necessary. In other embodiments, if the location and orientation of the components is outside of a maximum threshold, connections cannot be effectively made to the component. A separate warning may be made to the processors that the components are out of tolerance and that even with modification of the wiring connection, such connections will be compromised. Designs for wiring connections may take into account not only placement accuracy of the starting and ending points of the connection, but also wiring connection length. If a length of wire would be too long for effective operation and would cause, for example, excessive latency, then a warning may be generated to the processor that such wiring, if produced, would be out of specification. In the embodiments, connections are understood to mean electrical connections that are established with a component, such as a die of a microprocessor.

FIG. 7B is a flow diagram of a method 610 for causing a lithography process to be performed using metrology data. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other diagrams are possible.

At operation 710B, processing logic obtains first position data for a component of a substrate and an electrical connection pattern for the component for a designed state. For example, the first position data can include coordinate data. In some embodiments, the electrical connection pattern is a wiring connection pattern.

At operation 720B, processing logic causes a substrate to be scanned using a microlithography system to obtain second position data (e.g., coordinate data). For example, the substrate can be placed on stage of a microlithography system.

At operation 730B, processing logic compares the first position data with the second position data. The comparison can be used to determine at least one offset of the component scanned with the scanning device to the designed state.

At operation 740B, processing logic augments the electrical connection pattern based on the comparison to obtain an augmented pattern. For example, the augmentation can be performed based on the at least one offset.

At operation 750B, processing logic causes the augmented pattern to be manufactured.

In one example embodiment, a method for processing an apparatus in a lithography system is disclosed comprising obtaining coordinate data on a component and a connection pattern to the component in a designed state, placing the component within range of at least one scanning device associated with the lithography system, scanning the component with the at least one scanning device to develop a second set of coordinate data for the component, comparing the obtained coordinate data of the component to the second set of coordinate data to determine an offset of the component scanned with the scanning device to the designed state and augmenting the connection pattern to the component based, at least in part, upon one of the offset data, visual images of the scanning of the component used to develop the second set of coordinate data and the second set of coordinate data for the component.

In another non-limiting embodiment, the method may be performed wherein the component is placed upon a substrate.

In another non-limiting embodiment, the method may be performed wherein the substrate is placed upon an indexing table of the lithography system.

In another non-limiting embodiment, the method may be performed wherein the augmenting of the connection pattern is performed by computer analysis.

In another non-limiting embodiment, the method may be performed wherein the comparing the obtained coordinate data to the second set of coordinate data further comprises comparing the offset to a threshold.

In another non-limiting embodiment, the method may be further comprised when the offset is less than the threshold, setting the offset to zero.

In another non-limiting embodiment, the method may further comprise comparing the obtained coordinate data to the second set of coordinate data further comprises comparing the offset to a threshold and when the comparing is greater than the threshold, generating a warning to a user that the threshold has been exceeded.

In another non-limiting embodiment, the method may further comprise manufacturing the connection pattern based upon data of the augmented connection pattern.

In another example embodiment, a method for processing an apparatus in a microlithography system is disclosed comprising obtaining position data on a component and an electrical connection pattern to the component for a designed state, placing the component on a stage of a microlithography system, placing the stage within range of at least one scanning device of the microlithography system, scanning the stage including the component with the at least one scanning device to develop a second set of coordinate data for the component and the electrical connection pattern, comparing the obtained coordinate data of the component to the second set of coordinate data to determine an offset of the component scanned with the scanning device to the designed state and augmenting the electrical connection pattern to the component based, at least in part, upon the offset data.

In one example embodiment, the method may further comprise manufacturing the connection pattern based upon data of the augmented connection pattern.

In another example embodiment, the method may be performed wherein the component is placed upon a substrate.

In another example embodiment, the method may be performed wherein the augmenting of the connection pattern is performed by computer analysis.

In another example embodiment, the method may be performed wherein the comparing the obtained coordinate data to the second set of coordinate data further comprises comparing the offset to a threshold.

In another example embodiment, the method may be performed wherein the microlithography system is a maskless system.

In another example embodiment, the method may be performed wherein the comparing the obtained coordinate data to the second set of coordinate data further comprises comparing the offset to a threshold.

In one example embodiment, a method for processing a substrate in a microlithography system is disclosed comprising obtaining coordinate data in a designed state pertaining to at least one component and at least one wiring connection pattern to the at least one component, wherein the component is at least one of on and in the substrate, placing the substrate on a stage within the microlithography system, moving the substrate on the stage to a scanning device of the lithography system, scanning the substrate including the component with the scanning device to develop a second set of coordinate data for the component, comparing the obtained coordinate data of the component of the stage to the second set of coordinate data to determine an offset of the component scanned with the scanning device to the designed state and augmenting the at least one wiring connection pattern to the component based, at least in part, upon one of the offset data, visual images of the scanning of the component used to develop the second set of coordinate data and the second set of coordinate data for the component.

In another example embodiment, the method may further comprise manufacturing the at least one wiring connection pattern based upon data of the augmented connection pattern.

In another example embodiment, the method may be performed wherein the augmenting of the connection pattern is performed by computer analysis.

In a still further example embodiment, the method may be performed wherein the comparing the obtained coordinate data to the second set of coordinate data further comprises comparing the offset to a threshold.

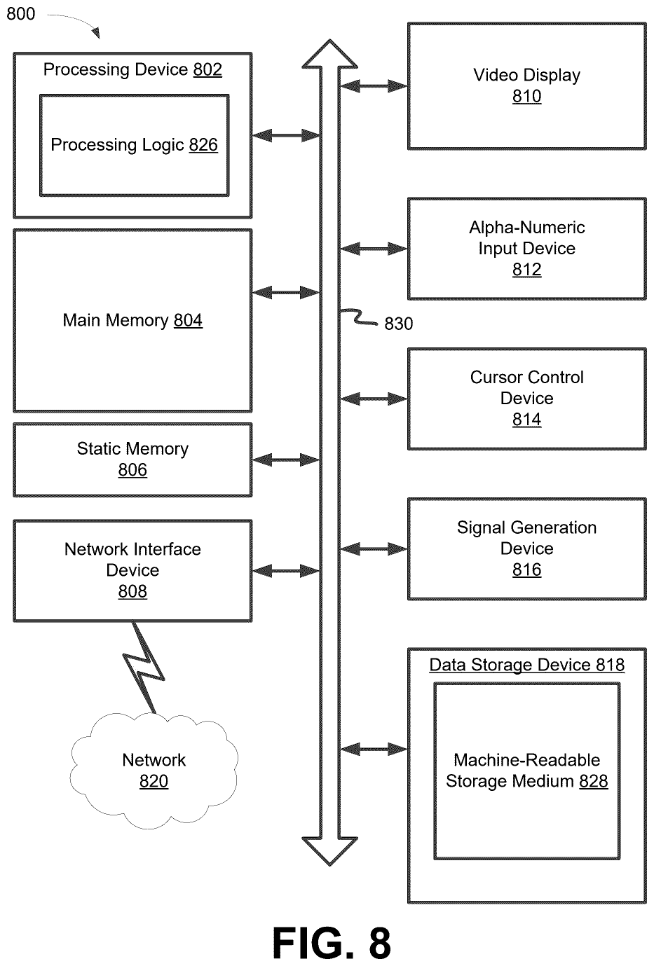

FIG. 8 illustrates a diagrammatic representation of a machine in the example form of a computer system 800 including a set of instructions executable by systems as described herein to perform any one or more of the methodologies discussed herein. In one implementation, the system may include instructions to enable execution of the processes and corresponding components shown and described in connection with FIGS. 1A-7B.

In alternative implementations, the systems may include a machine connected (e.g., networked) to other machines in a LAN, an intranet, an extranet, or the Internet. The machine may operate in the capacity of a server machine in client-server network environment. The machine may be a personal computer (PC), a neural computer, a set-top box (STB), Personal Digital Assistant (PDA), a cellular telephone, a server, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies described herein.

Computer system 800 can include processing device (processor) 802, main memory 804 (e.g., read-only memory (ROM), flash memory, dynamic random access memory (DRAM) such as synchronous DRAM (SDRAM)), static memory 806 (e.g., flash memory, static random access memory (SRAM)), and data object storage device 818, which communicate with each other via bus 830.

Processing device 802 can represent one or more general-purpose processing devices such as a microprocessor, central processing unit, or the like. More particularly, the processing device 802 may be a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. In various implementations of the present disclosure, the processing device 802 is configured to execute instructions for the devices or systems described herein for performing the operations and processes described herein.

Computer system 800 may further include network interface device 808. Computer system 800 also may include a video display unit 810 (e.g., a liquid crystal display (LCD) or a cathode ray tube (CRT)), alphanumeric input device 812 (e.g., a keyboard), cursor control device 814 (e.g., a mouse), and signal generation device 816 (e.g., a speaker).

Data storage device 818 may include computer-readable medium 828 on which is stored one or more sets of instructions of the devices and systems as described herein embodying any one or more of the methodologies or functions described herein. The instructions may also reside, completely or at least partially, within main memory 804 and/or within processing logic 826 of processing device 802 during execution thereof by computer system 800, main memory 804 and processing device 802 also constituting computer-readable media.

The instructions may further be transmitted or received over network 820 via the network interface device 808. While computer-readable storage medium 828 is shown in an example implementation to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing, encoding or carrying a set of instructions for execution by the machine and that cause the machine to perform any one or more of the methodologies of the present disclosure. The term “computer-readable storage medium” shall accordingly be taken to include, but not be limited to, solid-state memories, optical media, and magnetic media.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a memory; and
at least one processing device, operatively coupled with the memory, to:
obtain metrology data with respect to a substrate;
cause a lithography process to be performed using the metrology data to obtain a patterned substrate to be processed; and
cause a shortwave infrared (SWIR) inspection system to inspect the patterned substrate by focus averaging a plurality of images of the patterned substrate, wherein each image of the plurality of images corresponds to a respective SWIR wavelength of a plurality of SWIR wavelengths.

2. The system of claim 1, wherein the metrology data comprises at least one of die image data or via image data.

3. The system of claim 1, wherein to cause the lithography process to be performed, the at least one processing device is to:
obtain design data of a component disposed on the substrate;
scan an in-situ configuration of the component to obtain in-situ data;
identify at least one offset based on the design data and the in-situ data; and
augment at least one connection to the component based on the at least one offset.

4. The system of claim 3, wherein the design data comprises at least one of coordinate data of the component or a connection pattern to the component in a designed state.

5. The system of claim 1, wherein to cause the lithography process to be performed, the at least one processing device is to:
obtain first position data for a component disposed on the substrate and an electrical connection pattern;
cause the substrate to be scanned with a microlithography system to obtain second position data;
compare the first position data with the second position data to generate a comparison;
augment the electrical connection pattern based on the comparison to obtain an augmented pattern; and
cause the augmented pattern to be manufactured.

6. The system of claim 5, wherein to compare the first position data with the second position data, the at least one processing device is to determine at least one offset of the component scanned with the microlithography system.

7. The system of claim 1, wherein the plurality of images are captured by a single image sensor using the plurality of SWIR wavelengths.

8. A method comprising:
obtaining, by at least one processing device, metrology data with respect to a substrate;
causing, by the at least one processing device, a lithography process to be performed using the metrology data to obtain a patterned substrate to be processed; and
causing, by the at least one processing device, a shortwave infrared (SWIR) inspection system to inspect the patterned substrate by focus averaging a plurality of images of the patterned substrate, wherein each image of the plurality of images corresponds to a respective SWIR wavelength of a plurality of SWIR wavelengths.

9. The method of claim 8, wherein the metrology data comprises at least one of die image data or via image data.

10. The method of claim 8, wherein causing the lithography process to be performed comprises:
obtaining design data of a component disposed on the substrate;
scanning an in-situ configuration of the component to obtain in-situ data;
identifying at least one offset based on the design data and the in-situ data; and
augmenting at least one connection to the component based on the at least one offset.

11. The method of claim 10, wherein the design data comprises at least one of coordinate data of the component or a connection pattern to the component in a designed state.

12. The method of claim 8, wherein causing the lithography process to be performed comprises:
obtaining first position data for a component disposed on the substrate and an electrical connection pattern;
causing the substrate to be scanned with a microlithography system to obtain second position data;
comparing the first position data with the second position data to generate a comparison;
augmenting the electrical connection pattern based on the comparison to obtain an augmented pattern; and
causing the augmented pattern to be manufactured.

13. The method of claim 12, wherein comparing the first position data with the second position data comprises at least one offset of the component scanned with the microlithography system.

14. The method of claim 8, wherein the plurality of images are captured by a single image sensor using the plurality of SWIR wavelengths.

15. A system comprising:
a lithography system to perform a lithography process using metrology data to obtain a patterned substrate to be processed;
a shortwave infrared (SWIR) inspection system operatively coupled with the lithography system, the SWIR inspection system comprising:
at least one SWIR wave source to generate multiple SWIR waves each having a respective SWIR wavelength of a plurality of SWIR wavelengths;
a SWIR imaging system comprising an optical system and at least one image capture device operatively coupled with at least one image sensor;
a memory; and
at least one processing device, operatively coupled with the memory, to:
obtain the metrology data;
cause the lithography process to be performed using the metrology data to obtain the patterned substrate; and
cause the SWIR inspection system to inspect the patterned substrate by focus averaging a plurality of images of the patterned substrate, each image of the patterned substrate corresponding to a respective SWIR wavelength of the plurality of SWIR wavelengths.

16. The system of claim 15, wherein the metrology data comprises at least one of die image data or via image data.

17. The system of claim 15, wherein to cause the lithography process to be performed, the at least one processing device is to:
obtain design data of a component disposed on the substrate;
scan an in-situ configuration of the component to obtain in-situ data;
identify at least one offset based on the design data and the in-situ data; and
augment at least one connection to the component based on the at least one offset.

18. The system of claim 17, wherein the design data comprises at least one of coordinate data of the component or a connection pattern to the component in a designed state.

19. The system of claim 15, wherein to cause the lithography process to be performed, the at least one processing device to:
obtain first position data for a component disposed on the substrate and an electrical connection pattern;
cause the substrate to be scanned with a microlithography system to obtain second position data;
compare the first position data with the second position data to generate a comparison;
augment the electrical connection pattern based on the comparison to obtain an augmented pattern; and
cause the augmented pattern to be manufactured.

20. The system of claim 15, wherein the plurality of images are captured by a single image sensor using the plurality of SWIR wavelengths.
